(19) United States
(12) Patent Application Publication
(10) Pub. No.: US 2010/0219524 A1
(43) Pub. Date: Sep. 2, 2010

(54) CHIP SCALE PACKAGE AND METHOD OF FABRICATING THE SAME

(76) Inventors: Chi-Chih SHEN, Kaohslung City (TW); Jen-Chuan Chen, Bade City (TW); Wei-Chung Wang, Niaosong Township (TW)

Correspondence Address: Muncy, Geissler, Olds & Lowe, PLLC, 4000 Legato Road, Suite 310, FAIRFAX, VA, 22033, US

(21) Appl. No.: 12/574,382

(22) Filed: Oct. 6, 2009

(30) Foreign Application Priority Data
Feb. 27, 2009 (TW) 98106567

(51) Int. Cl. H01L 23/49; H01L 21/56; H01L 23/498

(52) U.S. Cl. 257/690; 438/127; 257/E21.502; 257/E23.024; 257/E23.06

(57) ABSTRACT

A chip scale package (CSP) package and method of fabricating the same are provided. The fabricating method includes the following steps. First, a substrate is provided. Next, a chip is disposed on the front surface of the substrate and electrically connected to the substrate. Then, a thermal conductive paste is formed on the surface of the chip. Afterwards, a molding compound for enclosing the chip is formed. Lastly, a milling process is applied to the molding compound so that the height of the molding compound is aligned with that of the thermal conductive paste. The chip can be disposed on the substrate by way of wire bonding or flip-chip bonding. The thermal conductive paste is disposed on the surface of the chip either before or after the milling process is completed.

This application claims the benefit of Taiwan application Serial No. 98106567, filed Feb. 27, 2009, the subject matter of which is incorporated herein by reference.

### BACKGROUND OF THE INVENTION

1. Field of the Invention

The invention relates in general to a package structure and a method of manufacturing the same, and more particularly to a chip scale package (CSP) structure with high heat dissipation efficiency and a method of manufacturing the same.

2. Description of the Related Art

Along with the advance in electronic technology, high-tech electronic products are available in the market one after another. The main purpose of the package industry is to support the research and development of electronic products and assure (1) the speed of semi-conductor packages continues to increase, (2) the functions of the semi-conductor packages are fully availed, and (3) the electronic products incorporating semi-conductor package posses the advantages of slimness, lightweight and compactness. In order to meet these requirements, the development of the semi-conductor packages is headed towards the objects of increasing the number of I/O pads, speeding the transmission of signals, boosting the power, shortening the pitches, increasing the connecting efficiency (the ratio of the scale of the chip inside the package to the scale of the package), multi-chip packaging, and so on. Thus, the lead-frame packaging no longer capable of satisfying the market needs. The package industry has gradually advanced from low-level packages such as dual-in-line package (DIP), small out-line package (SOP), and thin small outline package (TSOP) to IC carrier board package such as ball grid array (BGA) and flip chip grid array (FBGA), and even to high level packages such as chip scale package (CSP). The package structure is continually improved to satisfy the market needs. However, no matter how the structure is developed, the miniaturization in the appearance and high performance in heat dissipation have always been important objects to achieve for manufactures.

According to how the chip is disposed, the chip scale package (CSP) structure is divided into the wire bonding package and the flip-chip bonding package. In the wire bonding CSP structure, the heat is dissipated through a molding compound which ventilates the heat to the air. The flip chip CSP structure mainly has two ways for dissipating the heat. First, the flip chip structure transfers the heat to the substrate from the tin-lead protrusion and the filling material of the bottom layer, and then the heat is transferred to an external PCB through the substrate and the solder balls. Second, the heat is transferred upwardly and then is further ventilated to the air through the conductivity of the molding compound.

As the molding compound has poor conductivity, other methods are required to further improve the heat dissipation efficiency of the package structure. For example, a heat spread is passed above the chip to increase the thermal conductivity by way of the increased area and the high heat transmission coefficient of the heat spread. Of the chip scale package (CSP) structures currently available including the wire bonding and the flip chip CSP package structure alike, a complicated manufacturing process is required for disposing the heat spreader on the CSP structure to increase the heat-dissipation effect. Thus, the heat-dissipation effect is increased at the cost of an increased manufacturing cost.

Thus, how to fabricate a CSP structure having the advantages of high heat-dissipation effect and low manufacturing cost by using a simple manufacturing process has always been a goal to achieve for the manufacturers.

### SUMMARY OF THE INVENTION

The invention is directed to a chip scale package (CSP) structure and a method of manufacturing the same. The heat dissipation efficiency of the package structure is increased, the bond line thickness (BLT) of the package structure is controlled, and the package products being fabricated have the advantages of high heat dissipation efficiency and low thickness.

According to a first aspect of the present invention, a method of fabricating a, package structure is provided. The method includes the following steps. First, a substrate is provided. Next, a chip is disposed on the front surface of the substrate and is further electrically connected to the substrate. Then, a thermal conductive paste is formed on the surface of the chip. Afterwards, a molding compound for enclosing the chip is formed.

Finally, a milling process is applied to the molding compound so that the height of the molding compound is aligned with that of the thermal conductive paste. The chip can be disposed on the substrate by way of wire bonding or flip-chip bonding. The thermal conductive paste is disposed on the surface of the chip either before or after the milling process is completed.

The chip can be disposed on the substrate by way of wire bonding or flip-chip bonding, and the thermal conductive paste can be disposed on the surface of the chip either before or after the milling process is completed.

If the invention is adopted in a wire-bonded package structure, a thermal conductive paste can be formed on the front surface (the electrode surface) of the chip before the milling process is used for removing a part of the molding compound and a part of the thermal conductive paste.

If the invention is adopted in a flipped package structure, a thermal conductive paste can be formed on the rear surface of the chip before the milling process is used for removing a part of the molding compound and a part of the thermal conductive paste. Or, a photo-resist layer is formed on the rear surface of the chip and a molding compound is formed on the substrate before the milling process is used for removing a part of the molding compound. Next, the photo-resist layer is removed, and a thermal conductive paste is formed at the original position of the photo-resist layer, so that the height of the thermal conductive paste is aligned with that of the molding compound after the milling process is completed.

According to a second aspect of the present invention, a chip scale package (CSP) structure is provided. The CSP includes a substrate, a chip, a thermal conductive paste and a molding compound. The chip is bonded on the front surface of the substrate by way of wire bonding or flip-chip bonding. The thermal conductive paste is formed on the surface of the chip. The molding compound is for enclosing the chip, so that the height of the molding compound is aligned with that of the thermal conductive paste after a milling process is completed.

The invention will become apparent from the following detailed description of the preferred but non-limiting embodiments. The following description is made with reference to the accompanying drawings.

### BRIEF DESCRIPTION OF THE DRAWINGS

FIG. 1A˜FIG. 1H show a method of fabricating a CSP structure according to a first embodiment of the invention;

FIG. 2A˜FIG. 2H show a method of fabricating a CSP structure according to a second embodiment of the invention;

FIG. 3A˜FIG. 3I show a method of fabricating a CSP structure according to a third embodiment of the invention; and

FIG. 4A˜FIG. 4H show a method of fabricating a CSP structure according to a fourth embodiment of the invention.

### DETAILED DESCRIPTION OF THE INVENTION

The invention provides a chip scale package (CSP) structure and a method of manufacturing the same. The invention mainly employs a thermal conductive material and a specific fabricating process so that the package structure being fabricated can be equipped with a heat spreader for increasing heat dissipation efficiency. Moreover, according to the fabricating method of the invention, the bond line thickness (BLT), that is, the distance from the heat spreader to the surface of the chip, is controlled and reduced to a minimum. The lower the BLT is, the better the heat-dissipation effect and the thinner the overall thickness of the final product will be. Thus, the standards of the heat dissipation efficiency and the thickness of the package product fabricated according to the method of the invention meet customers' requirements.

A first to a fourth embodiment of the invention are disclosed below. In the first embodiment, the chip is bonded by way of wire bonding, but in the second to the fourth embodiment, the chip is bonded by way of flip-chip bonding. In the embodiments of the invention, a milling process is applied for controlling the BLT, so that the top surface of the molding compound is aligned with that of a thermal conductive material (such as a thermal conductive paste) after the milling process is completed. However, the package structure and the manufacturing process for fabricating the same disclosed in the embodiments of the invention are for exemplification only, not for limiting the scope of protection of the invention. Moreover, secondary elements are omitted in the embodiments of the invention for highlighting the technical features of the invention.

### First Embodiment

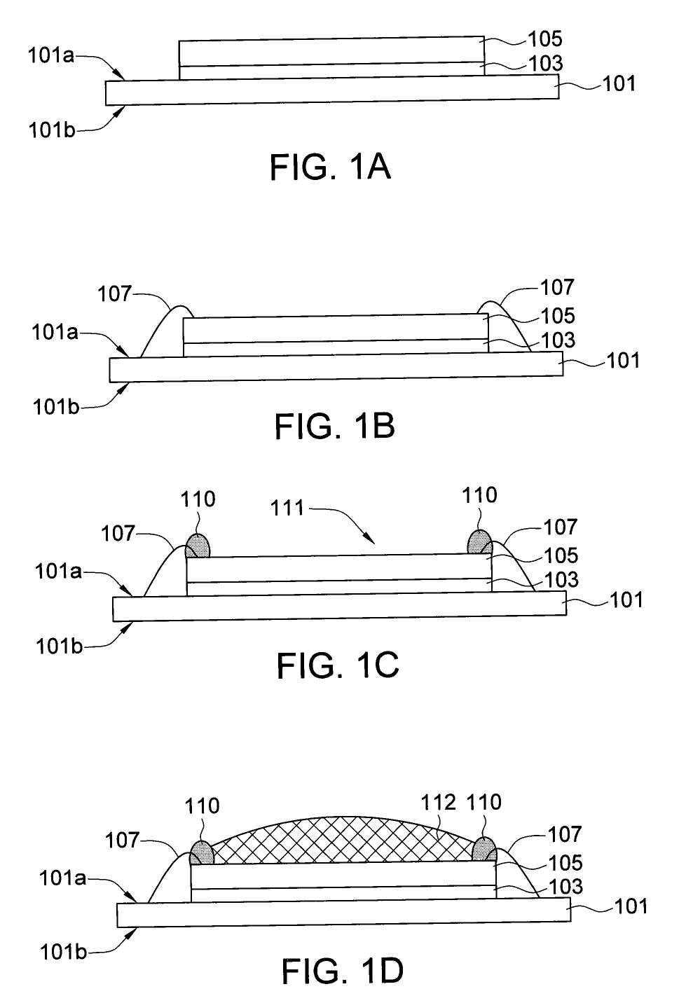

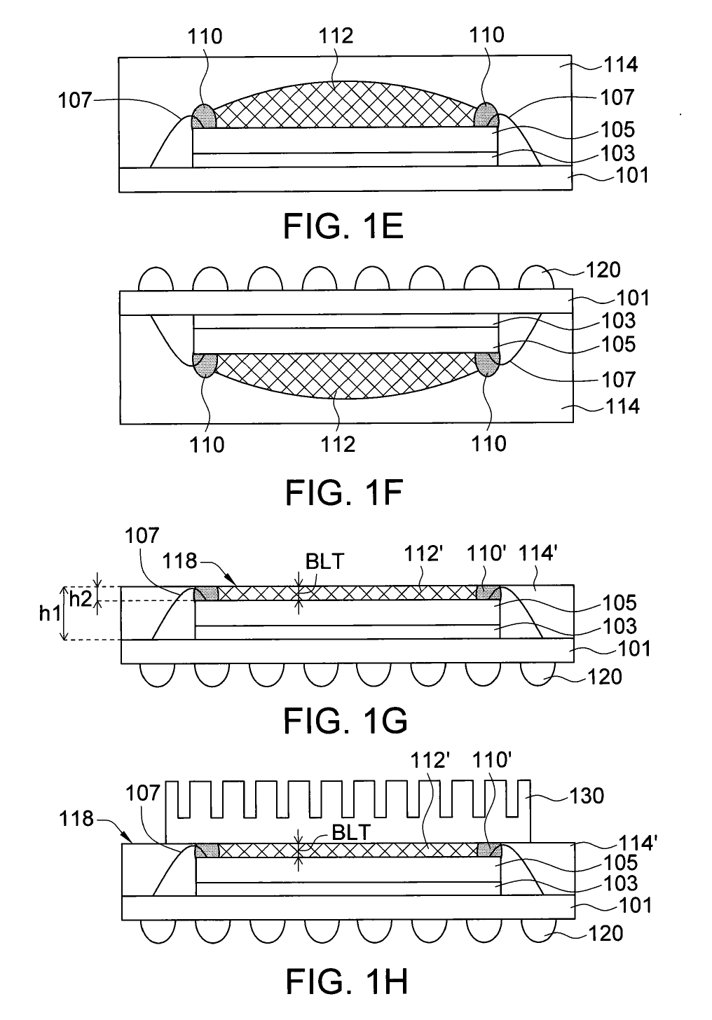

Referring to FIG. 1A˜FIG. 1H, a method of fabricating a CSP structure according to a first embodiment of the invention is shown. First, a substrate 101 is provided, and an adhesive 103 is used for fixing the rear surface of a chip 105 on the front surface 101a of the substrate 101, as shown in FIG. 1A. Next, a number of wires 107 are used for electrically connecting the front surface (the electrode surface) of the chip 105 with the substrate 101 by way of wire bonding, as shown in FIG. 1B.

Then, a dam-like non-conductive paste 110 is formed on the front surface of the chip 105, wherein the non-conductive paste 110 further covers the wires 107, as shown in FIG. 1C. The non-conductive paste 110 defines a receiving area 111 on the front surface of the chip 105. The non-conductive paste is made from a non-electrically conductive material such as epoxy or the like.

Afterwards, a thermal conductive paste 112 is filled within the receiving area 111. Then, a heating step is used for curing the thermal conductive paste 112 and the dam-like non-conductive paste 110, as shown in FIG. 1D. The thermal conductive paste 112 is made from a non-electrically conductive material such as epoxy or a similar material doped with the particles of an electrically-conductive metal to achieve high electrical conductivity and high thermal conduction.

As the wires 107 are enclosed by the non-conductive paste 110, the thermal conductive paste 112 being filled within the receiving area 111 does not contact the wires 107 and the short-circuiting problem is thus avoided. Moreover, if the viscosity of thermal conductive paste 112 is low, a dam-like non-conductive paste 110 is formed in advance to avoid the thermal conductive paste 112 overflowing outside the chip 105.

Next, a molding compound 114 is formed on the front surface 101a of the substrate 101 and covers the chip 105, the wires 107, the non-conductive paste 110 and the thermal conductive paste 112 as shown in FIG. 1E. Then, a ball-mounting step is applied for mounting a number of solder balls 120 on the rear surface 101b of the substrate 101, as shown in FIG. 1F.

Afterwards, a milling process is applied for removing a part of the molding compound 114, a part of the non-conductive paste 110 and a part of the thermal conductive paste 112, so that the height h1 of the molding compound 114′, the height h2 of the thermal conductive paste 112′ and the height h2 of the non-conductive paste 110′ are aligned with one another after the milling process is completed, as shown in FIG. 1G. After the milling process is completed, the molding compound 114′, the thermal conductive paste 112′ and the non-conductive paste 110′ preferably constitute a horizontal surface 118. Meanwhile, the height h2 of the thermal conductive paste 112′ determines the thickness (=h2) of the bond line thickness (BLT) of the package structure being fabricated.

Lastly, a heat spreader 130 is disposed on the thermal conductive paste 112′ being exposed as shown in FIG. 1H. The heat spreader 130 can be pasted on the top surface of the thermal conductive paste 112′ by using an adhesive (not illustrated), wherein the adhesive for fixing the heat spreader 130 is cured by way of heating.

According to the fabricating method of the first embodiment of the invention, the heat spreader can be easily disposed on a wire bonding CSP structure. Moreover, the bond line thickness (BLT) of the package structure being fabricated can be controlled through a milling process. Thus, in practical application, the value of BLT is determined according to the standard of heat dissipation efficiency for the product. Generally speaking, the lower the BLT is, the better the heat-dissipation effect and the thinner the overall thickness of the final product will be. After the milling process is completed, the height h2 of the non-conductive paste 110′ should at least be larger than the height of the wire loop of the wires 107 (for example, larger than or equal to 75 μm) to avoid short-circuiting.

### Second Embodiment

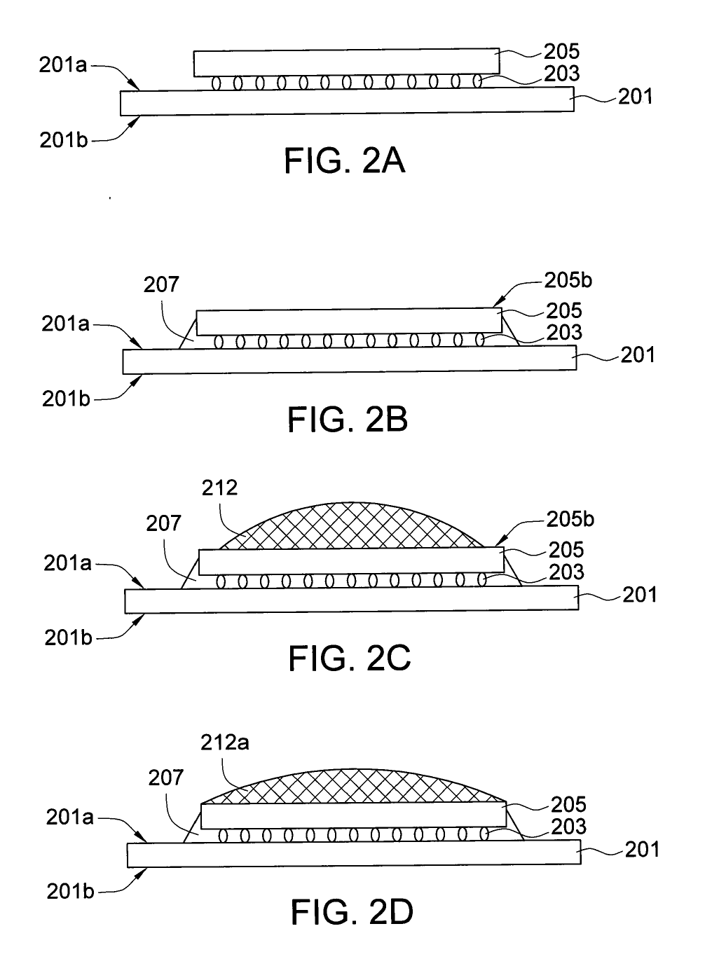

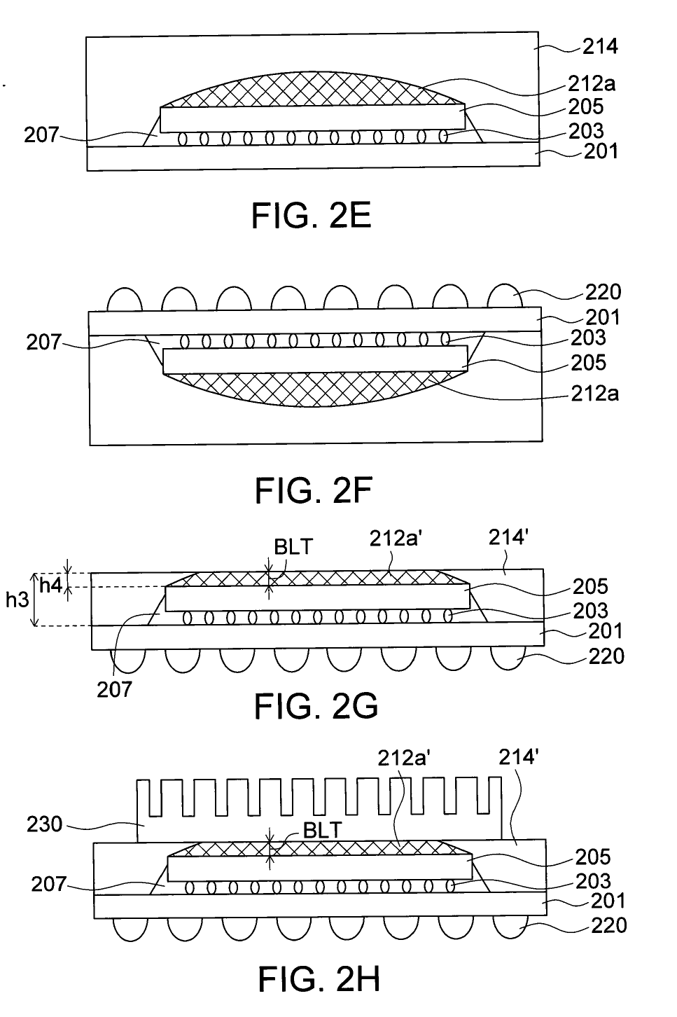

Referring to FIG. 2A˜FIG. 2H, a method of fabricating a CSP structure according to a second embodiment of the invention is shown. In the second embodiment, the chip is bonded by way of flip-chip bonding.

First, a substrate 201 is provided, and conductive bumps such as a tin-lead protrusion 203 is used for flip-bonding the chip 205 on the front surface 201a of the substrate 201 by way of soldering with the front surface (the electrode surface) of the chip 205 facing downward, as shown in FIG. 2A. Compared with the way of wire-bonding, the advantage of using the tin-lead protrusion is that the flip chip package largely increases the density of the input/output (I/O) contacts of the chip. Next, an underfill 207 can be selected and filled between the chip 205 and the substrate 201 as shown in FIG. 2B.

Then, as shown in FIG. 2C, a thermal conductive paste 212 is disposed on the surface (that is, the rear surface 205b) of the chip 205, and then the thermal conductive paste 212 is cured by way of heating. FIG. 2D shows the thermal conductive paste 212a being cured. The thermal conductive paste 212 is made from a non-electrically conductive material such as epoxy or a similar material doped with the particles of an electrically conductive metal to achieve high electrical conductivity and high thermal conduction.

Next, a molding compound 214 is formed on the front surface 201a of the substrate 201 and covers the chip 205 and the thermal conductive paste 212a, as shown in FIG. 2E. Then, a ball mounting step is applied to the rear surface 201b of the substrate 201 for mounting a number of solder balls 220, as shown in FIG. 2F.

Afterwards, a milling process is applied for removing a part of the molding compound 214 and a part of the thermal conductive paste 212a′, so that the height h3 of the molding compound 214′ is aligned with the height h4 of the thermal conductive paste 212a′ after the milling process is completed, as shown in FIG. 2G. Meanwhile, the bond line thickness (BLT) of the package structure being fabricated is determined according to the height h4 (BLT=h4) of the thermal conductive paste 212a′ after the milling process is completed.

Then, a heat spreader 230 is disposed on the thermal conductive paste 212a′ being exposed as shown in FIG. 2H. The heat spreader 230 can be pasted on the top surface of the thermal conductive paste 112′ by using an adhesive (not illustrated), wherein the adhesive for fixing the heat spreader 230 is cured by way of heating.

### Third Embodiment

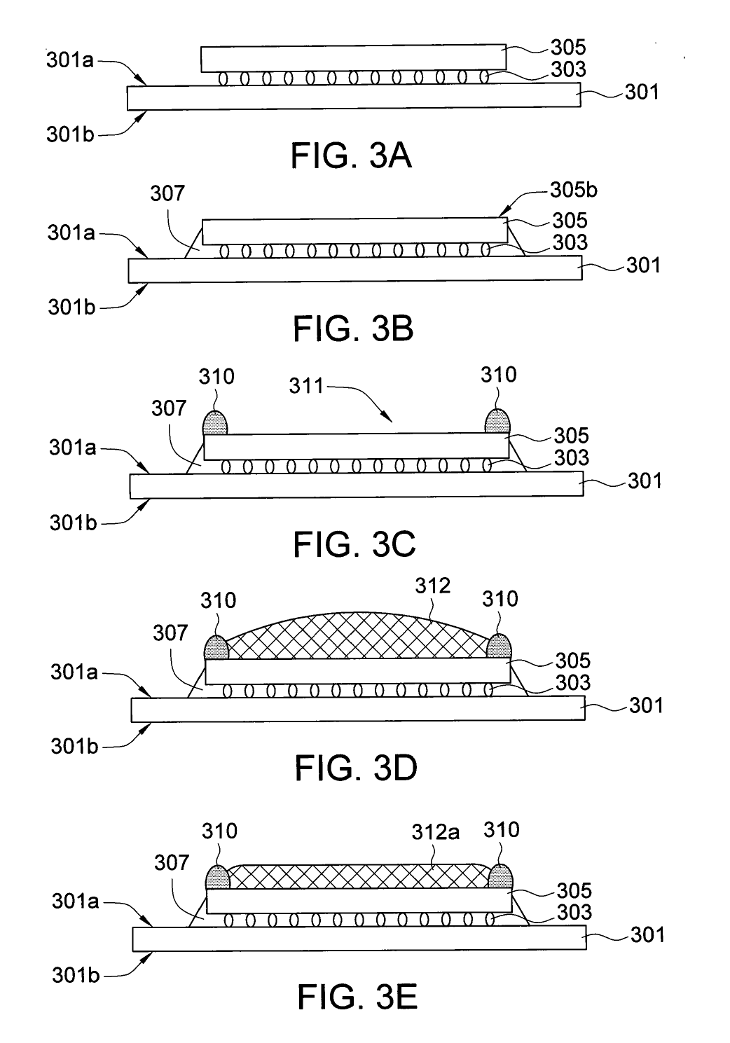

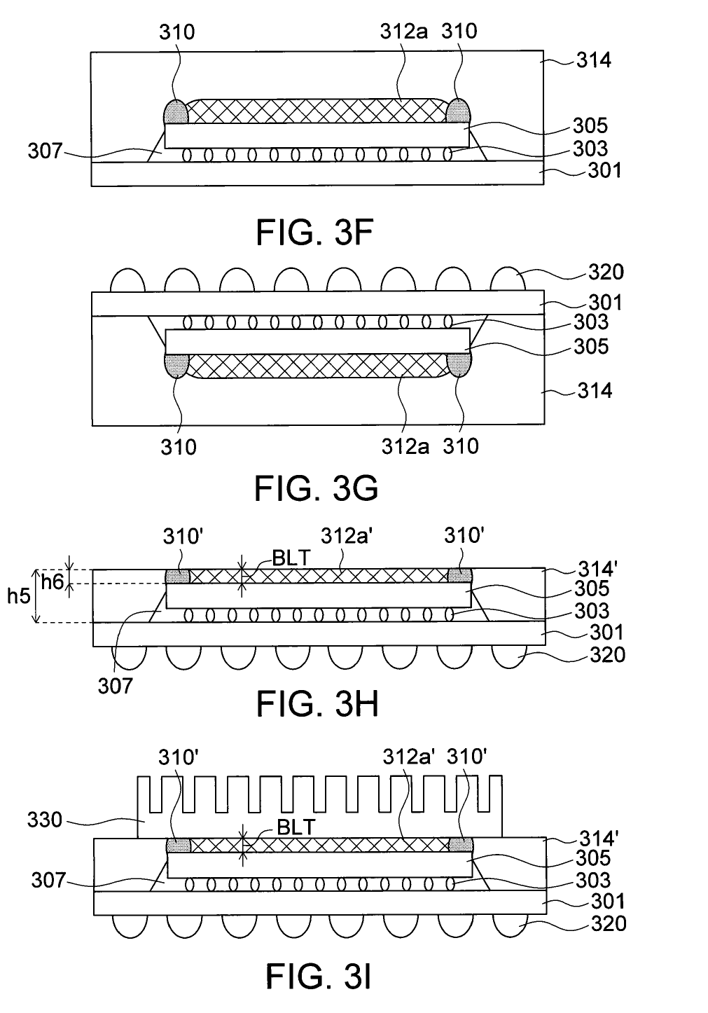

Referring to FIG. 3A˜FIG. 3I, a method of fabricating a CSP structure according to a third embodiment of the invention is shown. In the third embodiment, the chip is bonded by way of flip-chip bonding. The present embodiment is very similar to the second embodiment except that in the present embodiment, a dam-like non-conductive paste is formed before the thermal conductive paste is used to avoid the thermal conductive paste overflowing. The steps of the third embodiment are disclosed below.

First, a substrate 301 is provided, and conductive bumps such as a tin-lead protrusion 303 is used for flip-bonding the front surface of (the electrode surface) of the chip 305 on the front surface 301a of the substrate 301, as shown in FIG. 3A. It is noted that the chip 305 could be electrically connected with the substrate 301 other types of conductive materials, and tin-lead is merely exemplified as one material of conductive bumps. Next, an underfill 307 is selected and filed between the chip 305 and the substrate 301 as shown in FIG. 3B.

Then, a dam-like non-conductive paste 310 is disposed on the rear surface 305a of the chip 305 as shown in FIG. 3C. The non-conductive paste 310 defines a receiving area 311. Afterwards, a thermal conductive paste 312 is filled within the receiving area 311 as shown in FIG. 3D. After that, the thermal conductive paste 312 and the dam-like non-conductive paste 310 are cured by way of heating. FIG. 3E shows the thermal conductive paste 312a and the non-conductive paste 310 which are already cured. The non-conductive paste is made from a non-electrically conductive material such as epoxy or the like. The thermal conductive paste 112 is made from a non-electrically conductive material such as epoxy or a similar material doped with the particles of an electrically-conductive metal to achieve high electrical conductivity and high thermal conduction.

Next, a molding compound 314 is formed on the front surface 301a of the substrate 301 and covers the chip 305, the non-conductive paste 310 and the thermal conductive paste 312a, as shown in FIG. 3F. Moreover, a number of solder balls 320 are mounted on the substrate 301 of the rear surface 301b as shown in FIG. 3G.

Afterwards, a milling process is applied, so that the height h5 of the molding compound 314′ is aligned with the height h6 of the thermal conductive paste 312a′ after the milling process is completed, as shown in FIG. 3H. Meanwhile, the bond line thickness (BLT) of the package structure being formed is also determined according to the height h6 (BLT=h6) of the thermal conductive paste 312a′ being milled. Lastly, a heat spreader 330 is disposed on the thermal conductive paste 312a′ being exposed as shown in FIG. 3I.

### Fourth Embodiment

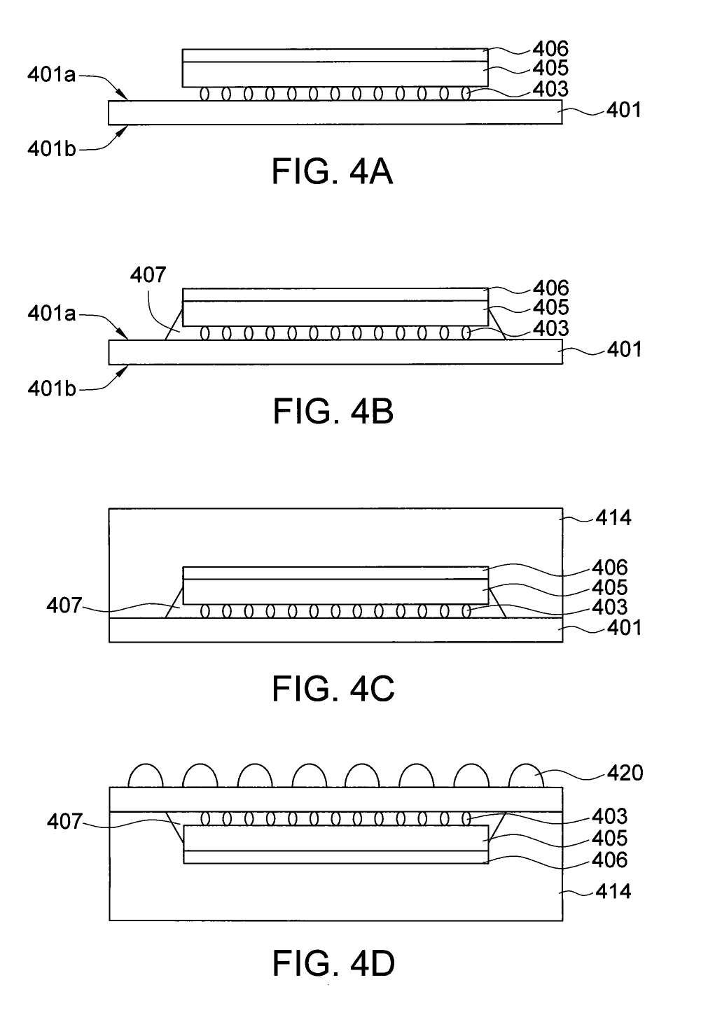

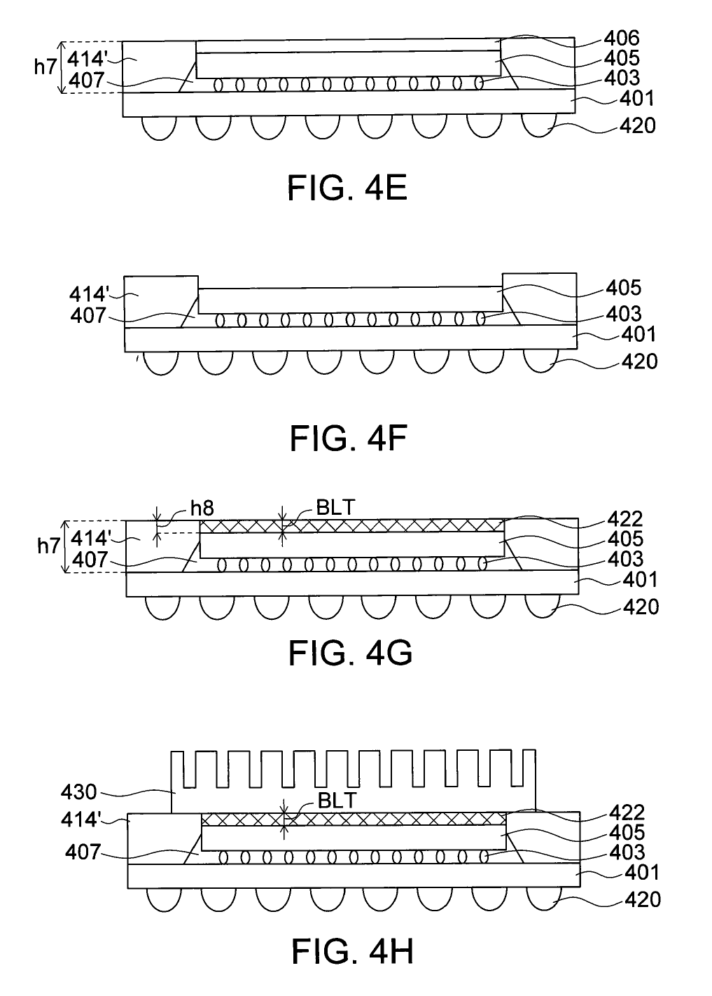

Referring to FIG. 4A˜FIG. 4H, a method of fabricating a CSP structure according to a fourth embodiment of the invention is shown. In the fourth embodiment, the chip is bonded by way of flip-chip bonding, and the way of forming the thermal conductive paste in the fourth embodiment is different from the way of forming the thermal conductive paste in the second and the third embodiment.

First, a substrate 401 is provided, and conductive bumps such as a tin-lead protrusion 403 is used for flip-bonding the chip 405 on the front surface 401a of the substrate 401 with the front surface (electrode surface) of the chip 405 facing downward. Next, a photo-resist layer 406 is formed on the rear surface of the chip 405 as shown in FIG. 4A. The photo-resist layer 406 is formed with a thickness of about 10 μm˜50 μm, and the actual value can be adjusted to fit actual needs.

Next, an underfill 407 is selected and filled between the chip 405 and the substrate 401, as shown in FIG. 4B.

Then, a molding compound 414 is formed on the front surface 401a of the substrate 401 and covers the chip 405 and the photo-resist layer 406, as shown in FIG. 4C. Moreover, a number of solder balls 420 are mounted on the rear surface 401b of the substrate 401, as shown in FIG. 4D.

Afterwards, a milling process is applied for removing a part of the molding compound 414 and exposing the photo-resist layer 406, as shown in FIG. 4E. After the milling process is completed, the height of the molding compound 414′ is h7. Besides, the milling process can be used for removing only a part of the molding compound 414 and/or a part of the photo-resist layer 406, and the invention does not impose any specific restriction thereto.

Next, the photo-resist layer 406 is removed as shown in FIG. 4F. Based on the characteristics of the photo-resist material, the photo-resist layer can be removed by way of dry etching, by using an organic solvent such as acetone, and the invention does not impose any specific restriction thereto.

Next, a thermal conductive paste 422 is formed on the rear surface of the chip 405 as shown in FIG. 4G. In the current step, the thermal conductive paste 422 can be dispersed on the rear surface of the chip 405 by way of printing, that is, at the original position of the photo-resist layer 406, and preferably, the height h8 of the thermal conductive paste 422 is aligned with the height h7 of the molding compound 414′ after the milling process is completed. Meanwhile, the bond line thickness (BLT) of the package structure being fabricated is determined according to the height h8 (BLT=h8) of the thermal conductive paste 422.

Lastly, a heat spreader 430 is disposed on the thermal conductive paste 422 being exposed as shown in FIG. 4H.

According to the fabricating method disclosed in the second to the fourth embodiment, the heat spreader can be easily disposed on a flip-chip bonding CSP structure. Moreover, the bond line thickness (BLT) of the package structure being fabricated can be controlled through a milling process, and the lower the BLT is, the better the heat-dissipation effect and the thinner the overall thickness of the final product will be. For a flip-chip bonding CSP structure using the fabricating method of the invention, the BLT can be minimized to about 10 μm, so that the package structure achieves high heat-dissipation and the thickness of the overall package structure is thinned at the same time.

By using the simple manufacturing process of the invention, a heat spreader can be easily disposed on a package structure to increase the heat dissipation efficiency for package structure without incurring extra manufacturing cost. Moreover, according to the fabricating method disclosed in the invention, the bond line thickness (BLT) of the package structure can be easily controlled. The lower the BLT is, the better the heat-dissipation effect and the thinner the overall thickness the final product will be. Hence, the package structure fabricated according to the fabricating method of the invention has the advantages of high heat dissipation efficiency and low thickness.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method of fabricating a package structure, comprising:
providing a substrate having a front surface and a rear surface;
disposing a chip on the front surface of the substrate and electrically connecting the chip with the substrate;
forming a thermal conductive paste on a surface of the chip;
forming a molding compound for enclosing the chip; and
applying a milling process to the molding compound, so that the height of the molding compound is aligned with the height of the thermal conductive paste after the milling process is completed.

2. The fabricating method according to claim 1, wherein the chip is electrically connected to the substrate via a plurality of wires.

3. The fabricating method according to claim 2, wherein after the step of disposing the chip, the method further comprises:
forming a dam-like non-conductive paste on the chip and covering the wires, wherein the dam-like non-conductive paste defines a receiving area on the surface of the chip;
filling the thermal conductive paste within the receiving area; and
curing the dam-like non-conductive paste and the thermal conductive paste.

4. The fabricating method according to claim 3, further comprising:
forming the molding compound on the front surface of the substrate and covering the chip, the wires, the non-conductive paste and the thermal conductive paste;
performing a ball-mounting step to the rear surface of the substrate; and
applying a milling process to the molding compound, the non-conductive paste, and the thermal conductive paste, so that the height of the molding compound, the height of the thermal conductive paste and the height of the non-conductive paste are aligned with one another.

5. The fabricating method according to claim 4, wherein after the milling process is completed, the method further comprises:
disposing a heat spreader on the thermal conductive paste.

6. The fabricating method according to claim 1, wherein the chip is electrically connected to the substrate by way of flip-chip bonding.

7. The fabricating method according to claim 6, wherein after the thermal conductive paste is formed on the surface of the chip, the method further comprises the step of curing the thermal conductive paste.

8. The fabricating method according to claim 7, wherein after the step of curing the thermal conductive paste, the method further comprises:
forming the molding compound on the front surface of the substrate and covering the chip and the thermal conductive paste;
forming a plurality of solder balls on the rear surface of the substrate; and
applying the milling process to the molding compound and the thermal conductive paste, so that the height of the molding compound is aligned with the height of the thermal conductive paste.

9. The fabricating method according to claim 6, wherein after the chip is disposed, the method further comprises:
forming a dam-like non-conductive paste on the chip, wherein the non-conductive paste defines a receiving area on the surface of the chip;
filling the thermal conductive paste within the receiving area; and
curing the dam-like non-conductive paste and the thermal conductive paste.

10. The fabricating method according to claim 9, after the step of curing the non-conductive paste and the thermal conductive paste, the method further comprises:
forming the molding compound on the front surface of the substrate and covering the chip, the non-conductive paste and the thermal conductive paste;
forming a plurality of solder balls on the rear surface of the substrate; and
applying the milling process to the molding compound, the non-conductive paste, and the thermal conductive paste, so that the height of the molding compound, the height of the thermal conductive paste and the height of the non-conductive paste are aligned with one another.

11. A method of fabricating a package structure, comprising:
providing a substrate having a front surface and a rear surface;
disposing a chip on the front surface of the substrate and electrically connecting the chip with the substrate;
forming a photo-resist layer on a rear surface of the chip;
forming a molding compound on the front surface of the substrate and covering the chip and the photo-resist layer;
applying a milling process to the molding compound for exposing the photo-resist layer;
removing the photo-resist layer for exposing the rear surface of the chip; and
forming a thermal conductive paste on the rear surface of the chip, and the height of the molding compound aligned with the height of the thermal conductive paste.

12. The fabricating method according to claim 11, wherein after the milling process is completed, the method further comprises:
disposing a heat spreader on the thermal conductive paste.

13. A chip scale package (CSP) structure, comprising:
a substrate having a front surface and a rear surface;
a chip disposed on the front surface of the substrate and electrically connected with the substrate;
a thermal conductive paste disposed on the chip; and
a molding compound for enclosing the chip, wherein the height of the molding compound is aligned with the height of the thermal conductive paste after a milling process is completed.

14. The structure according to claim 13, wherein the chip is electrically connected with the substrate via a plurality of wires.

15. The structure according to claim 14, further comprising:
a dam-like non-conductive paste disposed on the periphery of a front surface of the chip to define a receiving area, wherein the non-conductive paste encloses wire loops of the wires, and the thermal conductive paste is filled within the receiving area.

16. The structure according to claim 15, wherein the height of the molding compound, the height of the thermal conductive paste and the height of the non-conductive paste are aligned with one another.

17. The structure according to claim 13, wherein the chip is electrically connected with the substrate with a plurality of conductive bumps.

18. The structure according to claim 17, further comprising:
a dam-like non-conductive paste disposed on the periphery of a rear surface of the chip to define a receiving area, wherein the thermal conductive paste is filled within the receiving area.

19. The structure according to claim 18, wherein the height of the molding compound, the height of the thermal conductive paste and the height of the non-conductive paste are aligned with one another.

20. The structure according to claim 13, further comprising a heat spreader disposed on the thermal conductive paste.
